(19) United States
(12) Patent Application Publication
(10) Pub. No.: US 2008/0271991 A1
(43) Pub. Date: Nov. 6, 2008

(54) Apparatus and Method for Supercritical Fluid Removal or Deposition Processes

(75) Inventors: Michael B. Korzenski, Danbury, CT (US); Eliodor G. Ghenciu, King of Prussia, PA (US); Chongying Xu, New Milford, CT (US); Thomas H. Baum, New Fairfield, CT (US); Pamela M. Visintin, Red Hook, NY (US)

Correspondence Address: MOORE & VAN ALLEN PLLC, P.O. BOX 13706, Research Triangle Park, NC, 27709, US

(73) Assignee: Advanced Technology Materials , Inc., Danbury, CT (US)

(21) Appl. No.: 11/911,615

(22) PCT Filed: Apr. 17, 2006
(86) PCT No.: PCT/US06/14321

§ 371 Date: Jul. 21, 2008

Related U.S. Application Data
(60) Provisional application No. 60/671,852, filed on Apr. 15, 2005.
(60) Provisional application No. 60/672,170, filed on Apr. 15, 2005.

(51) Int. Cl. C23C 14/00

(52) U.S. Cl. 204/192.32; 204/298.33

(57) ABSTRACT

A continuous-flow supercritical fluid (SCF) apparatus and method for the deposition of thin films onto microelectronic devices or the removal of unwanted layers, particles and/or residues from microelectronic devices having same thereon. The SCF apparatus preferably includes a dynamic mixer to ensure homogeneous mixing of the SCF and other chemical components.

### FIELD OF THE INVENTION

The present invention relates to a supercritical fluid apparatus useful in microelectronic device manufacturing and a process of using said apparatus for removal or deposition processes including, but not limited to, etching, cleaning, particle removal, residue removal, thin-film deposition and photoresist layer removal from microelectronic devices.

### DESCRIPTION OF THE RELATED ART

Significant and continuing efforts have been made in the microelectronic device manufacturing industry to develop improved processes for etching, cleaning and removing ion-implant hardened photoresists and residues thereof from the microelectronic device. This effort has been frustrated by the continuing and rapid decrease in critical dimensions. Conventional wet-cleaning methods, including the use of aqueous-based compositions, suffer substantial limitations as critical dimension (CD) widths decrease below 100 nm due in part to the high surface tension characteristics of liquids used in the cleaning solution. Additionally, aqueous cleaning solutions can strongly affect important material properties of porous low-k dielectric materials, including mechanical strength, moisture uptake, coefficient of thermal expansion, and adhesion to different substrates.

In addition to removal processes, there are numerous applications in which it is desired to form layers on microelectronic devices, for example, thin-film deposition during fabrication of integrated circuitry. Among the methods commonly utilized for layer formation are chemical vapor deposition (CVD) processes and atomic layer deposition (ALD) processes. Problems associated with CVD and/or ALD processes include less than 100% step coverage, slow deposition rate, and the inefficient conversion of precursor to deposited material.

Recently, the utilization of supercritical fluids (SCFs) to deliver precursors to a surface for film formation thereon has been proposed. Supercritical fluids are typically utilized by first dissolving a precursor within the supercritical fluid at high concentration, taking advantage of the solvent characteristics of the SCF. The precursor-containing SCF is then delivered to a reaction chamber having a substrate positioned therein. Subsequently, (i) the temperature and/or pressure conditions within the chamber are reduced so that the fluid is changed to a non-supercritical state. The fluid then lacks the solvent properties which can keep the precursor in solution, and the precursor falls out of solution to form a layer (or a film) on the substrate. Alternatively, (ii) the substrate is heated and the precursor in the precursor-containing SCF decomposes at the substrate to form a layer on the substrate.

Supercritical Fluid Deposition (SCFD) has important advantages over chemical vapor deposition (CVD) including, but not limited to: (1) low operating temperatures, which permits the use of organometallic precursors that might otherwise degrade at the high temperatures necessary for generating vapor phase concentrations in CVD; (2) the achievement of higher (SCF-phase) precursor concentrations due to the solvating power of the SCF's while simultaneously facilitating ligand desorption from the metal surface after decomposition of the organometallic complex thereon; (3) the simultaneous dissolution of multiple precursors in the SCF, enabling the SCF-phase precursor composition to be tuned to deposit materials with complex and multi-elemental compositions; (4) the option to use organometallic precursor compounds with labile ligands because vacuum conditions are not used; (5) the use of non-volatile organometallic precursors, which tend to be less toxic and more cost effective compounds; and (6) the use of non-toxic, low cost, readily available and recyclable solvents such as carbon dioxide.

Current SCFD processing techniques are based on either the rapid expansion of supercritical solvent (RESS) or the reduction of a precursor at a substrate surface, either thermally or reactively using a carrier or co-reactive gas, e.g., hydrogen. RESS involves the rapid expansion of the precursor-containing SCF through a nozzle or capillary of micron size dimension, subsequently creating an aerosol of the material to be deposited at or near the substrate surface. Although this process may accommodate the growth of thin films of various materials, the deposition rate and surface area of the deposited film is limited due to the small amount of precursor material that is expandable through the small dimension nozzle necessary for the expansion of the fluid. Further, particle generation of non-uniform film growth may result. The latter process, often called chemical fluid deposition (CFD), involves the solvation of the precursor material to be deposited in the SCF and transportation of the precursor-containing SCF to the deposition chamber through a standard opening, followed by the reaction, e.g., reduction or decomposition, of the precursor at the substrate under static pressure. This process permits the growth of uniform films, however, a high percentage of precursor material is lost to the chamber walls due to heat dissipation from the heating source. Additionally, an increased level of film contamination from organic ligands has been reported due to the long exposure times of the precursor-containing SCF in the chamber.

Supercritical fluids (SCF) also provide an alternative method for removing materials, e.g., photoresist layers, and other residues from the microelectronic device surface. SCFs diffuse rapidly, have low viscosity, near zero surface tension, and can penetrate easily into deep trenches and vias. Further, because of their low viscosity, SCFs can rapidly transport dissolved and/or suspended species. Cleaning processes using SCFs greatly eliminate water consumption, damage to the wafer, the need for large quantities of hazardous liquid chemicals which must be disposed of, and the number of processing steps.

Unfortunately, SCFs are highly non-polar and as such, many species are not adequately solubilized therein. Presently, components added to SCFs for solubilization therein include, but are not limited to, one or more of precursors, complexes, co-reactants, diluents, co-solvents, surfactants, oxidizing agents, reducing agents, stabilizers, chelating agents, passivators, complexing agents, and etchants. Said components are usually incorporated into the SCF using static mixing methods, whereby the SCF and the component(s) to be solubilized therein are introduced to a mixing chamber and the momentum of the flowing fluids is utilized to provide the energy necessary for physical mixing by impingement upon tortuous paths, which convert forward momentum into transverse or turbulent movement. Any change in pressure or temperature in static mixers, such as a pressure drop, may result in solid precipitation or liquid-liquid phase separation within the mixing chamber which has downstream ramifications. For example, the apparatus plumbing downstream of the mixing chamber may become clogged, or particles may form within the process chamber. Further, the advantages associated with a SCF composition, such as the ability to penetrate easily into deep trenches and vias for effective cleaning therein or the achievement of higher (SCF-phase) precursor concentrations due to the solvating power of the SCF's, is eliminated when the SCF and component(s) separate.

Accordingly, there is a need in the art for an improved method of mixing, such as a dynamic mixer, which will produce a uniform and homogeneous media of the component(s) in the bulk solvent, even when a component is a solid or has a known low solubility in the bulk solvent.

In addition to the problems associated with static mixing chambers, present removal systems are arranged to recirculate the SCF cleaning formulations. The recirculation of spent fluid over the substrate to be cleaned does not allow for fresh incoming chemistry, which is necessary to ensure effective and efficient cleaning of the microelectronic device surface.

Accordingly, there is also a need in the art for a continuous-flow system which allows for the uniform introduction of fresh chemistries to the microelectronic device surface for the efficient and effective removal of unwanted layers, particles and/or residue. Preferably, the dynamic mixer is a component of the continuous-flow system. Importantly, a continuous-flow system will also improve the growth process of thin film materials, thereby ensuring the deposition of more uniform, less contaminated films.

### SUMMARY OF THE INVENTION

The present invention relates to a continuous-flow SCF apparatus and processes of using said apparatus.

In one aspect, the invention relates to a continuous-flow supercritical fluid (SCF) apparatus, said SCF apparatus comprising:
(a) a solvent container holding a solvent;
(b) a high pressure solvent pump communicatively connected to the solvent container for flowing the solvent downstream of the high pressure solvent pump;
(c) a solvent heater communicatively connected to and positioned downstream of the high pressure solvent pump, wherein the solvent heater is arranged to convert the solvent into a supercritical state;
(d) a high pressure chemical component pump for flowing at least one chemical component downstream of the chemical component pump;
(e) a mixing chamber communicatively connected to and positioned downstream of both the solvent heater and the chemical component pump; and
(f) a process chamber communicatively connected to and positioned downstream of the solvent heater, and the mixing chamber.

In another aspect, the present invention relates to a continuous-flow supercritical fluid process chamber comprising:
(a) an interior chamber;
(b) a fluid disperser positioned within the interior chamber;
(c) a microelectronic device support positioned within the interior chamber, arranged to support one or more microelectronic devices; and
(d) at least two exhaust ports distally positioned relative to the fluid disperser.

In yet another aspect, the present invention relates to a method of manufacturing a microelectronic device, said method comprising depositing a thin film onto the microelectronic device using a continuous-flow supercritical fluid deposition (SCFD) apparatus, said SCFD apparatus comprising:
(a) a solvent container holding a solvent;
(b) a high pressure solvent pump communicatively connected to the solvent container for flowing the solvent downstream of the high pressure solvent pump;
(c) a solvent heater communicatively connected to and positioned downstream of the high pressure solvent pump, wherein the solvent heater is arranged to convert the solvent into a supercritical state;
(d) a high pressure precursor chemical pump for flowing at least one chemical component downstream of the precursor chemical pump;
(e) a mixing chamber communicatively connected to and positioned downstream of both the solvent heater and the precursor chemical pump; and
(f) a process chamber communicatively connected to and positioned downstream of the solvent heater, and the mixing chamber.

In yet another aspect, the present invention relates to a method of depositing a thin film, said method comprising depositing a thin film onto a substrate using a continuous-flow supercritical fluid deposition (SCFD) apparatus, said SCFD apparatus comprising:
(a) a solvent container holding a solvent;
(b) a high pressure solvent pump communicatively connected to the solvent container for flowing the solvent downstream of the high pressure solvent pump;
(c) a solvent heater communicatively connected to and positioned downstream of the high pressure solvent pump, wherein the solvent heater is arranged to convert the solvent into a supercritical state;
(d) a high pressure precursor chemical pump for flowing at least one chemical component downstream of the precursor chemical pump;
(e) a mixing chamber communicatively connected to and positioned downstream of both the solvent heater and the precursor chemical pump; and
(f) a process chamber communicatively connected to and positioned downstream of the solvent heater, and the mixing chamber.

In yet another aspect, the present invention relates to a continuous-flow supercritical fluid deposition (SCFD) apparatus, said SCFD apparatus comprising:
(a) a container holding a mixture of at least one solvent and at least one precursor material;
(b) a high pressure pump communicatively connected to the container for flowing the mixture downstream of the high pressure pump;
(c) a heater communicatively connected to and positioned downstream of the high pressure pump, wherein the heater is arranged to convert the mixture into a subcritical or supercritical state; and
(d) a process chamber communicatively connected to and positioned downstream of the heater.

In yet another aspect, the present invention relates to a continuous-flow supercritical fluid deposition (SCFD) apparatus, said SCFD apparatus comprising:
(a) a solvent container holding a solvent;
(b) a high pressure solvent pump communicatively connected to the solvent container for flowing the solvent downstream of the high pressure solvent pump;
(c) a solvent heater communicatively connected to and positioned downstream of the high pressure solvent pump, wherein the solvent heater is arranged to convert the solvent into a supercritical state;
(d) a high pressure precursor chemical pump for flowing a precursor downstream of the precursor chemical pump; and
(e) a process chamber communicatively connected to and positioned downstream of both the solvent heater and the precursor chemical pump, wherein the process chamber comprises a mixing system.

Yet another aspect of the invention relates to improved microelectronic devices, and products incorporating same, made using the methods and systems of the invention comprising depositing a thin film using the methods and/or systems described herein, and optionally, incorporating the microelectronic device into a product.

Still another aspect of the invention relates to a dynamic mixing system for the homogenization of a supercritical or subcritical fluid and at least one component, said mixing system comprising:
(a) a high pressure vessel defining an interior chamber;
(b) a supercritical or subcritical fluid container holding the supercritical or subcritical fluid, said supercritical or subcritical fluid container arranged in feed relationship with the high pressure vessel;
(c) at least one component container holding the at least one component, said at least one component container arranged in feed relationship with the high pressure vessel; and
(d) an agitator positioned within the interior chamber to provide dynamic mixing.

In a further aspect, the invention relates to a dynamic mixing system for the homogenization of a supercritical or subcritical fluid and at least one other component selected from the group consisting of co-solvents, etchants, surfactants, oxidizing agents, reducing agents, passivators, precursors, complexing agents, chelating agents, and other chemical additives, said mixing system comprising:
(a) a high pressure vessel defining an interior chamber;
(b) a single source reagent container holding a supercritical or subcritical fluid and at least one other component, said single source reagent container arranged in feed relationship with the high pressure vessel; and
(c) an agitator positioned within the interior chamber to provide dynamic mixing.

In another aspect, the invention relates to a continuous-flow supercritical or subcritical fluid (SCF) apparatus, said apparatus comprising:
(a) a single source fluid container holding a solvent source reagent and at least one other component source reagent;
(b) a high pressure pump communicatively connected to the single source container for flowing the single source fluid downstream of the high pressure pump;
(c) single source fluid heater communicatively connected to and positioned downstream of the high pressure pump, wherein the single source fluid heater is arranged to convert the single source fluid into a supercritical or subcritical state; and
(d) a process chamber communicatively connected to and positioned downstream of the single source fluid heater.

In still another aspect, the invention relates to a continuous-flow supercritical or subcritical fluid (SCF) apparatus, said apparatus comprising:
(a) a solvent container holding a solvent source reagent;
(b) a high pressure pump communicatively connected to the solvent container for flowing the solvent source reagent downstream of the high pressure pump;
(c) a solvent source reagent heater communicatively connected to and positioned downstream of the high pressure pump, wherein the solvent source reagent heater is arranged to convert the solvent source reagent into a supercritical or subcritical state;
(d) a chemical formulation pump for flowing a chemical formulation downstream of the chemical formulation pump; and
(e) a process chamber communicatively connected to and positioned downstream of both the solvent source reagent heater and the chemical formulation pump, wherein the process chamber includes a mixing system.

In a further aspect, the invention relates to a method of removing hardened photoresist material from a microelectronic device having said photoresist material thereon using the continuous-flow supercritical fluid (SCF) apparatus described herein.

In another aspect, the invention relates to a method of manufacturing a microelectronic device, said method comprising removing hardened photoresist material from a microelectronic device having said photoresist material thereon using the continuous-flow supercritical fluid (SCF) apparatus described herein.

Yet another aspect of the invention relates to improved microelectronic devices, and products incorporating same, made using the methods and systems of the invention comprising removing photoresist material using the methods and/or systems described herein, and optionally, incorporating the microelectronic device into a product.

Other aspects, features and embodiments of the invention will be more fully apparent from the ensuing disclosure and appended claims.

### BRIEF DESCRIPTION OF THE DRAWINGS

FIG. 1 is a cut away view of the SCFD process chamber according to the invention.

FIG. 2 is a cut away view of the SCFD process chamber according to the invention including the axis indicator L-L′ and relative distance indicators M-M′, N-N′ and P-P′.

FIG. 3 is a cut away view of the SCFD process chamber including the resistive cartridge heaters according to the invention.

FIG. 4 is a cut away view of the SCFD process chamber including the heating element substrate support according to the invention.

FIG. 5A is a elevational view of the heating element substrate support according to the invention.

FIG. 5B is a cross-sectional view of the heating element substrate support of FIG. 5A.

FIG. 6 is a schematic diagram of the components of the continuous-flow apparatus according to the invention.

FIG. 7 is a cut away view of the dynamic mixing chamber according to the invention.

FIG. 8a is a scanning electron micrograph of the control wafer (top left 60° angle view) before processing.

FIG. 8b is a scanning electron micrograph of the control wafer (right 90° cross section view) before processing.

FIG. 8c is a scanning electron micrograph of the control wafer of FIG. 8a after processing using an apparatus including a static mixer and a recirculator.

FIG. 8d is a scanning electron micrograph of the control wafer of FIG. 8b after processing using an apparatus including a static mixer and a recirculator.

FIG. 8e is a scanning electron micrograph of the control wafer of FIG. 8a after processing using an apparatus including a static mixer and fresh chemistries thereby simulating continuous flow.

FIG. 8f is a scanning electron micrograph of the control wafer of FIG. 8b after processing using an apparatus including a static mixer and fresh chemistries thereby simulating continuous flow.

FIG. 8g is a scanning electron micrograph of the control wafer of FIG. 8a after processing using an apparatus including a static mixer and dilute fresh chemistries thereby simulating continuous flow.

FIG. 8h is a scanning electron micrograph of the control wafer of FIG. 8b after processing using an apparatus including a static mixer and dilute fresh chemistries thereby simulating continuous flow.

FIG. 8i is a scanning electron micrograph of the control wafer of FIG. 8a after processing using the continuous-flow apparatus of FIG. 6 and a dynamic mixer.

FIG. 8j is a scanning electron micrograph of the control wafer of FIG. 8b after processing using the continuous-flow apparatus of FIG. 6 and a dynamic mixer.

### DETAILED DESCRIPTION OF THE INVENTION, AND PREFERRED EMBODIMENTS THEREOF

The present invention contemplates a continuous-flow supercritical fluid process chamber and apparatus for the deposition of thin films onto microelectronic devices. Preferably, the continuous-flow apparatus includes a dynamic mixing system.

In addition, the present invention relates to fluid delivery systems for processing of microelectronic devices, including etching, cleaning, particle removal, residue removal, and other known fabrication steps, using supercritical fluids. Specifically, the present invention further relates to the removal of hardened photoresist from a microelectronic device using a continuous-flow apparatus and process. Preferably, the continuous-flow apparatus includes a dynamic mixing system.

The term “supercritical fluid” is used herein to denote a material which is under conditions of not lower than a critical temperature, T_{c}, and not less than a critical pressure, P_{c}, in a pressure-temperature diagram of an intended compound. The preferred supercritical fluid employed in the present invention is CO₂ which may be used alone or in an admixture with another additive such as Ar, NH₃, N₂, CH₄, C₂H₄, CHF₃, C₂H₆, n-C₃H₈, H₂O, N₂O and the like. Importantly, although reference is made to supercritical fluids, the present invention also contemplates the use of other dense fluids, for example subcritical fluids. As defined herein, “subcritical fluid” describes a solvent in the subcritical state, i.e., below the critical temperature and/or below the critical pressure associated with that particular solvent. In other words, the fluid is not in the supercritical state, but rather is a gas or a liquid of varying density.

As defined herein, “microelectronic device” corresponds to resist-coated semiconductor substrates, flat panel displays, thin-film recording heads, microelectromechanical systems (MEMS), and other advanced microelectronic components. The microelectronic device may include patterned and/or blanketed silicon wafers, flat panel display substrates or fluoropolymer substrates. Further, the microelectronic device may include mesoporous or microporous inorganic solids. It is to be understood that the phrase “depositing a thin film onto the microelectronic device” is not meant to be limiting in any way and includes the deposition of a thin film onto any substrate that will eventually become a microelectronic device.

As defined herein, “high pressure vessel” includes a mixing chamber as well as the process chamber. Importantly, the process chamber may include mixing capabilities so that the process chamber is also the mixing chamber, and vice versa.

“Hardened photoresist” as used herein includes, but is not limited to, undeveloped photoresist, developed photoresist, cross-linked photoresist, photoresist that has been plasma etched, e.g., during back-end-of-line (FEOL) dual-damascene processing of integrated circuits, and/or photoresist that has been ion implanted, e.g., during front-end-of-line (FEOL) processing to implant dopant species in the appropriate layers of the semiconductor wafer. It is to be understood that the phrases “removing hardened photoresist material from a microelectronic device” and “contacting the microelectronic device with a removal composition” are not meant to be limiting in any way and includes the removal of hardened photoresist material from, and the contacting of any substrate that will eventually become a microelectronic device.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

The continuous-flow apparatus and process described herein may be employed for (i) the growth of thin films onto a microelectronic device using supercritical or subcritical fluid mediums and/or (ii) etching, cleaning, residue removal, thin-film deposition and the removal of layers and/or residue from a microelectronic device, preferably layers including hardened photoresist, using supercritical or subcritical fluid mediums. Specific reference to supercritical fluids hereinafter in the broad description of the invention is meant to provide an illustrative example of the present invention and is not meant to limit same in any way.

Growth of Thin Films onto a Microelectronic Device

The microelectronic device may include patterned and/or blanketed silicon wafers, flat panel display substrates or fluoropolymer substrates. Thin films may also be deposited into mesoporous or microporous inorganic solids. Supercritical fluids have gas-like transport properties (e.g., low viscosity and absence of surface tension) that ensure rapid penetration of the pores.

The deposited thin films may include a metal, mixture of metals, metal alloy, metal oxide, metal sulfide, mixed metal oxides, mixed metal sulfides, insulator, dielectric material, or low-k dielectric material. In some embodiments, the thin film comprises multiple metals and thus the precursor comprises multiple precursors for the corresponding multiple metals. Furthermore, the thin films may be a homogeneous or non-homogeneous mixture of multiple metals, for example, the material may be a platinum/nickel mixture or alloy, or a copper mixture or alloy. Moreover, gradients of varying concentrations of individual metals may be created throughout a deposited thin film.

In a continuous-flow supercritical fluid deposition (SCFD) process, prior to introducing SCF solution containing at least one solvent and at least one precursor into the process chamber, the process chamber is filled with neat solvent (which is the same as the solvent in the precursor solution) at supercritical pressure and supercritical temperature. Thereafter, the SCF solution is continuously added to the process chamber containing at least one microelectronic device, as precursor decomposition products or unused reactants are continuously removed from the process chamber. The flow rates into and out of the process chamber are approximately equal so that the pressure within the process chamber remains substantially constant, ensuring the maintenance of a supercritical state and uniform precursor concentration. The overall flow rate is optimized according to the particular reaction.

Solubility of the precursor in the supercritical solvent at the reaction conditions can be verified in a variable volume view cell, which is well known in the art (e.g., McHugh et al, Supercritical Fluid Extraction: Principles and Practice; Butterworths: Boston, 1986). Known quantities of precursor and supercritical solvent are loaded into the view cell, where they are heated and compressed to conditions at which a single phase is optically observed.

The temperature and pressure of the SCFD process depends on the precursor(s) and choice of solvent. Generally, temperature is less than 250° C. and often less than 100° C., while the pressure is typically between 50 and 500 bar. A temperature gradient between the microelectronic device and solution can also be used to enhance chemical selectivity.

Continuous-flow SCFD processes require the careful monitoring and control of the flow rate of the precursor-containing SCF to the SCFD chamber to control the growth rate of the film. Nozzles of micron-size dimension, such as those typically associated with RESS chambers, are not able to accommodate the larger fluid flows necessary for a uniform distribution of the precursor-containing SCF over a wide area. Moreover, there is a maximum flow rate associated with these nozzles which is often lower than that needed to control the growth rate of the film grown using continuous-flow SCFD. At the other end of the spectrum, the standard fluid delivery openings associated with CFD chambers are typically so large that fine fluid flow rate control is impossible.

Showerhead delivery overcomes the deficiencies of the prior art fluid delivery mechanisms. More particularly, a showerhead disperser in the practice of the present invention may include a housing enclosing an interior volume therewithin, wherein the housing is joined in flow communication with a supply of precursor-containing SCF. The housing includes a wall defining a discharge face of the disperser, such wall having an array of discharge passages therein for discharge of the precursor-containing SCF to a deposition locus in proximity to the wall and in fluid-receiving relationship thereto. The discharge passages are in spaced-apart relation to one another, forming a corresponding array of discharge passage openings at the discharge face. Preferably, the showerhead is devoid of any electrodes.

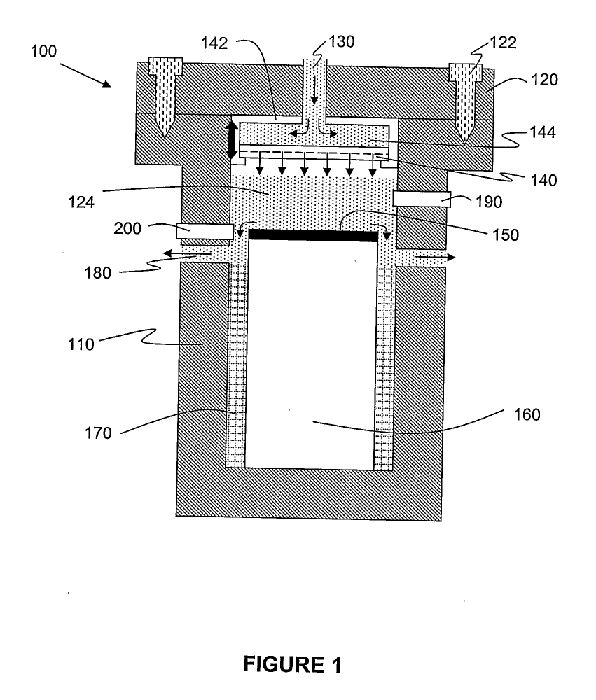

Referring to FIG. 1, a SCFD process chamber 100 that may be employed for the growth of thin films from sub- and supercritical fluid media, is illustrated. The high pressure chamber container 110 and high pressure top 120 defining the interior chamber 124 may be connected using connecting means 122, for example, bolts or the equivalent thereof rated to withstand the high pressures associated with supercritical fluids. The interior chamber 124 preferably has a variable volume in a range from about 45 cm³ to about 60 cm³. It is to be appreciated by one skilled in the art that the SCFD process chamber may have a single contiguous construction or may include more than 2 components, as long as it defines an interior volume. As such, the SCFD process chamber is not limited to a matebly engageable container 110 and top 120 as shown schematically in FIG. 1.

The chamber top 120 includes an opening for the passage of a high pressure line 130 therethrough. The high pressure line communicates with interior volume 144, which is defined by the housing 142 and the fluid disperser 140, wherein the fluid disperser is most preferably a showerhead. As illustrated by the double-headed arrow, the housing 142 is axially adjustable along the length of the container 110 to vary the distance between the fluid disperser 140 and the substrate 150. Means for axially adjusting the distance of the fluid disperser 140 relative to the substrate 150 are determinable by one skilled in the art, e.g., a threaded shaft whereby the housing 142 is screwable up and down along the shaft. The substrate is positioned upon the substrate support 160, which may include a heating element. Optionally, the substrate support 160 is circumscribed by an insulating material 170, e.g., an alumina-containing ceramic material or equivalent thereof. It is to be appreciated by one skilled in the art that the walls of the high pressure container 110 define a circular, elliptical or polygonal interior chamber 124.

In practice, the high pressure line 130 delivers precursor-containing SCF to the interior chamber 124 through the fluid disperser 140 having a multiplicity of perforations, thus creating a uniformly distributed shower of the precursor-containing SCF solution. Importantly, the supercritical state of the precursor-containing fluid is maintained upstream and downstream of the fluid disperser 140, however, it is noted that the temperature and pressure upstream and downstream of the fluid disperser may be the same or different. Upon introduction to the heated microelectronic device 150, the precursor species thermally decompose thereon.

Notably, the housing 142, which may be axially moved to adjust the distance between the fluid disperser 140 and the substrate 150, provides additional control over the residence time of the precursor-containing fluid species. It is well known in the art that control over residence time minimizes precursor decomposition in the precursor-containing solution, which minimizes particle contamination of the growing film. Additionally, the axially adjustable fluid disperser may minimize the total area of the interior walls of the high pressure container 110 exposed to the precursor-containing SCF, thereby minimizing precursor losses due to deposition at the chamber walls.

The thin film growth rate and uniformity of the thin film grown may also be controlled by improvements in the SCFD process chamber exhaust port design. In general, SCFD process chambers include only one exhaust port, typically located on the bottom or back-end of the SCFD chamber, which can result in the non-homogeneous spread of the precursor-containing SCF over the microelectronic device surface.

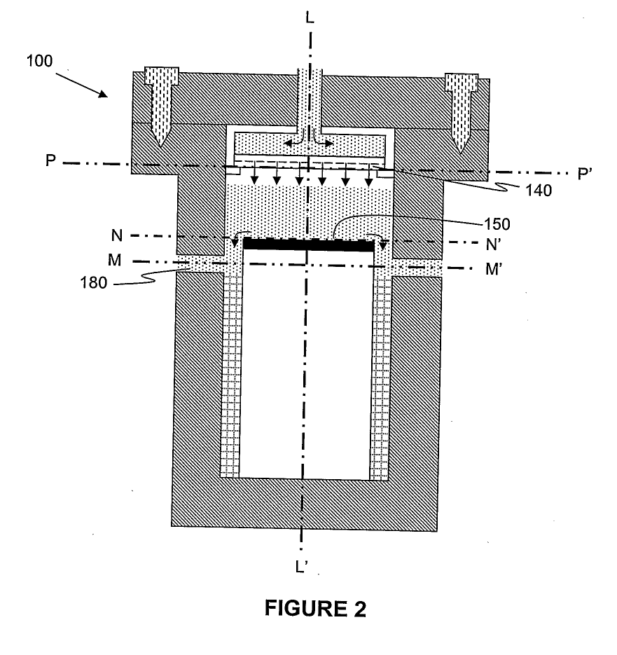

Referring to FIG. 1, a multiplicity of outlet ports 180 are distally positioned relative to the fluid disperser 140. As defined herein, “distally positioned relative to the fluid disperser” refers to an axial distance relative to the fluid disperser that is greater than the axial distance relative to the exposed surface of the substrate. Referring to FIG. 2, which represents the SCFD chamber 100 of FIG. 1, the axial length of the chamber is represented by line L-L′. The fluid disperser 140, exposed surface of the substrate 150 and outlet ports 180 are represented by lines P-P′, N-N and M-M′, respectively. In other words, “distally positioned relative to the fluid disperser” corresponds to an arrangement whereby the distances |((M-M′)−(P-P′))|>|((N-N′)−(P-P′)) along the L-L′ axis.

Analogously, as defined herein, “proximally positioned relative to the fluid disperser” refers to an axial distance relative to the fluid disperser that is less than the axial distance relative to the exposed surface of the substrate. Referring to FIG. 2, “proximally positioned relative to the fluid disperser” corresponds to an arrangement whereby the distances |((N-N′)−(P-P′))|>|((M-M′)−(P-P′))| along the L-L′ axis. The incorporation of multiple outlet ports, distally positioned relative to the fluid disperser, in combination with a continuous flow of fluid ensures a uniform flow of precursor-containing fluid over the heated microelectronic device and hence the deposition of an increasingly more uniform film upon the exposed surface of the substrate.

Preferably, in addition to being distally positioned relative to the fluid disperser, the outlet ports are located proximately to the substrate to minimize the exposed surface area of the interior walls of the high pressure container 110 and the substrate support 160. Most preferably, the absolute distance from M-M′ to N-N′ is in a range from about 5% to about 20% of the overall length of the chamber 100 along the L-L′ axis.

It is to be appreciated that at least two outlet ports 180 are preferably symmetrically positioned about the circumference of the high pressure container 110 of the SCFD chamber 100 in the same plane. Although not illustrated in FIG. 1, the number of outlet ports may be greater than two so long as the engineering of the SCFD chamber walls is not compromised. Preferably, the number of outlet ports 180 is in a range from about 2 to about 10. It is also to be appreciated that the at least two outlet ports may be non-symmetrically positioned about the circumference of the container 110 or in different planes along the L-L′ axis.

In addition, the SCFD chamber 100 of FIG. 1 may include at least one internally positioned thermocouple, located in proximity to the substrate to monitor the temperature of the fluid near the substrate, at least one pressure transducer in proximity relative to the fluid disperser, and at least one rupture disk.

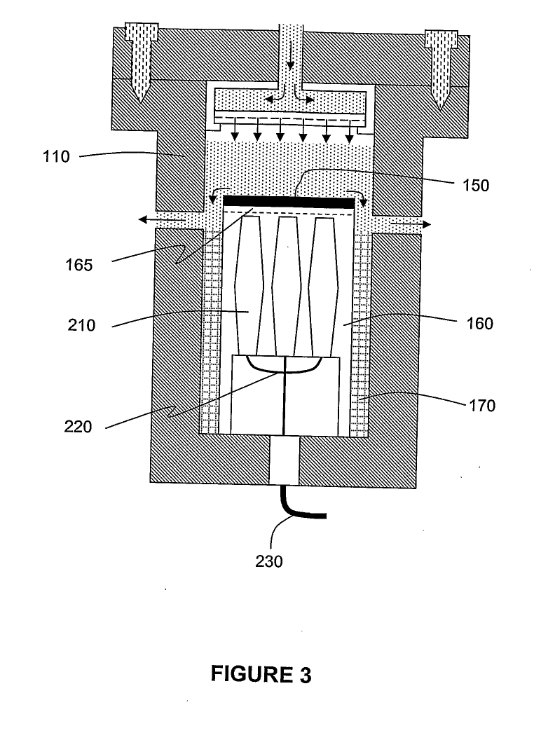

The efficiency of the growth process and the quality of the thin film grown may also be controlled by a heater located at or within the substrate support. Referring to FIG. 3, where similar components are numbered analogously to FIG. 1, at least one resistive cartridge heater 210 may be located within the substrate support 160. The resistive cartridge heater 210 is electrically connected via connections 220 to a power supply 230 and optionally a temperature gauge. Thermocouples may be positioned internally and externally at both the center and the edge of the substrate support surface to monitor the temperature across the entire dimension of the heated substrate. It is to be appreciated that although three cartridge heaters 210 are shown schematically in FIG. 3, the present invention is not limited to the use of exactly three cartridge heaters, i.e., more or less may be used.

The heat generated by the cartridge heaters 210 is preferably localized in the head 165 of the substrate support. As defined herein, the “head” of the substrate support corresponds to that portion of the substrate support that is located proximately to the substrate (as approximated using the dotted line in FIG. 3).

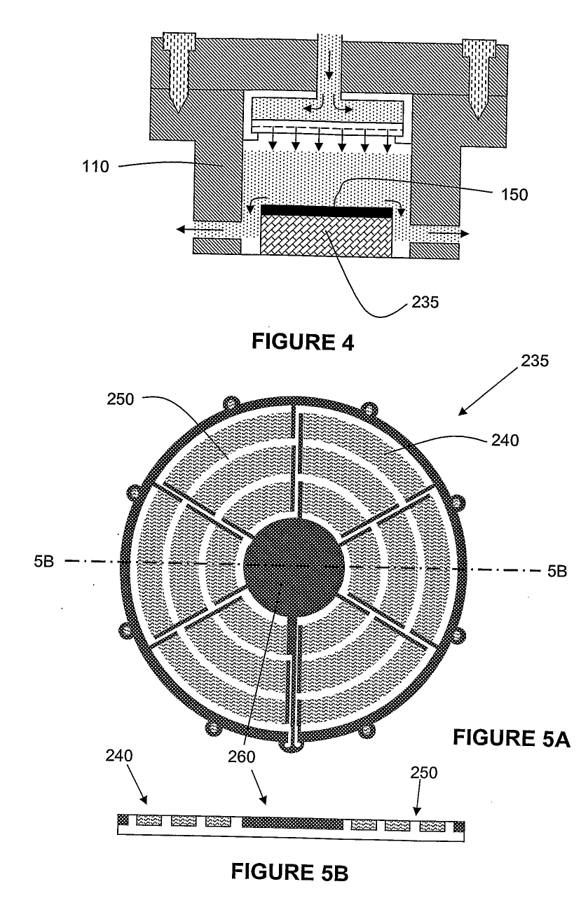

Alternatively, referring to FIGS. 4, 5A and 5B, the heating element 235 is the substrate support (FIG. 4) and features a conductive thin film 240, and an insulator or heating element 260, applied to the surface of an insulating microelectronic device 250. Accordingly, the entire surface of the substrate support becomes the active heat source, which provides more efficient energy transfer. Advantageously, thin film heating requires low watt density and less power for improved energy efficiency, and as a result of the extremely small thickness of the heating element substrate support 235, e.g., 0.3 μm, it possesses low thermal inertia for fast heating response and more accurate temperature control. Furthermore, the low mass of the heating surface allows for diminished heat dissipation to the walls of the reaction chamber.

The advantages of these heating designs are twofold: first, since the surface area of the chamber is minimized, the amount of precursor material lost due to deposition at the interior walls of the SCFD chamber is minimized with a concomitant increase in substrate deposition efficiency; and second, since the heat is localized at the head of the substrate support and heat loss from the sides of the holder is minimal, the necessity of power compensation due to energy losses is minimized.

Fine control of the thickness of the film deposited with minimal loss of precursor material may also be achieved using a pulsed method of growing films from precursor-containing SCF solutions. Once optimization of growth parameters such as showerhead/substrate distance, substrate temperature and SCF density have been realized, a growth process similar to atomic layer epitaxy (ALE) may be achieved through a pulsed delivery of the precursors to the process chamber.

This pulsed delivery is similar to a continuous flow, dynamic process but differs in that the precursor-containing fluid is delivered directly to the process chamber in a pulsed manner and the chamber exhaust is always open and regulated by a back-pressure regulator downstream of the process chamber. Pulsed delivery allows the decomposing precursor material to migrate on the substrate surface, thus forming a uniform layer of the film to be deposited before being covered by the next incoming pulse. By controlling the number of pulses, a fine control of film thickness may be achieved with minimal loss of precursor material.

Pulsed delivery may also prevent blockage of the fluid disperser perforations. Pulsed delivery eliminates the need for cooling the fluid disperser because cooling is achieved by the constant flow of pure SCCO₂ into the process chamber. The heated precursor-containing fluid is intermittently pulsed into the process chamber through a pulse valve positioned upstream of the fluid disperser. Preferably, the pulse valve is automated to periodically open and close in order to achieve the desired pulsing effect. Accordingly, the amount of time the heated precursor resides in the fluid disperser perforations is minimal and concomitantly, blockage of said perforations is substantially decreased.

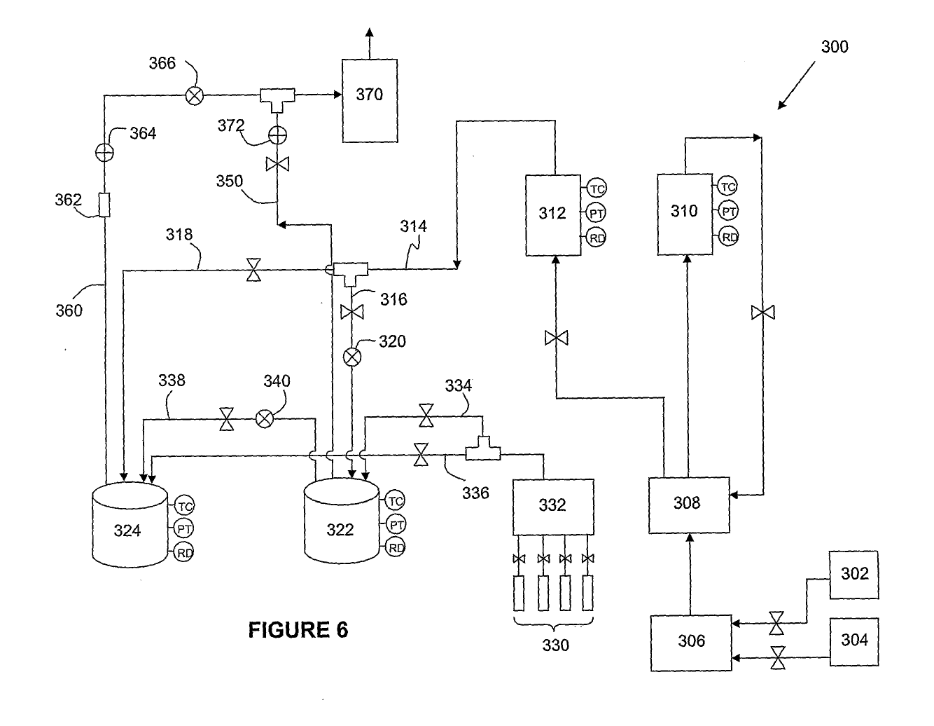

A schematic of a SCFD apparatus 300 of the present invention is shown in FIG. 6. Carbon dioxide from a container of CO₂ 302, having a measurable head pressure, e.g., 800-850 psi, is delivered to a gas booster 306. House air or nitrogen 304 is also introduced to the gas booster to compress the pistons therein to help convert the CO₂ from a gaseous to a highly pressurized, dense liquid state.

The dense liquid CO₂ is directed to a high pressure pump 308. While off-line, the dense CO₂ may circulate through a CO₂ chiller 310 for delivery back to the high pressure pump 308. Without the CO₂ chiller, the liquid carbon dioxide may eventually reach equilibrium temperature with the environment whereby the CO₂ may convert to the gaseous phase. Therefore, in any liquid carbon dioxide system, it is desirable to keep the fluid in circulation and continuously being cooled. Further, once the pump is primed with liquid fluid and the cooling system running, the pump is most efficient if it can remain operating. Previously cooled, stagnant fluid can only heat up, and once the gas phase develops it can be difficult to prime the pump and then recommence operation. The CO₂ chiller 310 and the CO₂ heater 312 may be equipped with a thermocouple (TC), a pressure transducer (PT) and a rupture disc (RD).

During deposition, the dense liquid CO₂ is pumped to a CO₂ heater 312 to convert the highly pressurized liquid into the supercritical phase. A portion of the supercritical CO₂ in line 314 may be directed to a mixing chamber 322 via CO₂ mixing chamber line 316, while the remainder may be directed to a process chamber 324 via CO₂ process chamber line 318. The CO₂ mixing chamber line 316 may include a high pressure check valve 320, which allows the fluid to flow upstream of the valve but not in reverse. Importantly, the constant flow of SCCO₂ directed to the process chamber 324 serves to cool the fluid disperser thus minimizing clogging of the fluid disperser, as previously discussed.

The mixing chamber 322 may be a static mixer or a dynamic mixer, preferably a dynamic mixer whereby the bulk solvent, co-solvent and chemical precursor(s) are thoroughly mixed. The dynamic mixing chamber of the present invention may be used to mix a wide variety of solid/liquid suspension systems, including simple, dilute fluid suspensions as well as complex, concentrated slurries which may exhibit anomalous viscosity characteristics. An example of a dynamic mixer includes the mixer disclosed in U.S. Provisional Patent Application No. 60/672,170, filed Apr. 15, 2005 in the name of Michael B. Korzenski et al. for “Apparatus and Method of Pre-Mixing Supercritical Fluid Removal Formulations for Removal Processes,” which is incorporated herein by reference in the entirety, and hereinbelow. Notably, the apparatus of the invention may include just a dynamic mixer, just a static mixer, or both depending on the nature of the precursor(s). Most preferably, the SCF and precursor(s) are mixed using a dynamic mixer.

The process chamber 324 may be any chamber necessary for such thin film deposition process. For example, the process chamber may be the chamber disclosed herein in FIGS. 1, 3 and 4, or alternatively, any other chamber required for the desired deposition process, as readily determinable by one skilled in the art. The chamber may be a batch or single wafer chamber, for continuous, pulsed or static deposition.

Concurrently, precursor solution components from precursor component containers 330 are introduced into the precursor chemical pump 332 for pre-mixing therein. Precursor chemical pump 332 is a high pressure liquid pump. Although, four (4) precursor component containers 330 are illustrated in FIG. 6, more or less containers are contemplated herein, as required for the particular material to be deposited. Precursor solution components include, but are not limited to: source reagent (precursor) compound(s), complex(es) and material(s); co-solvent(s); co-reactant(s); surfactant(s); chelating agent(s); diluent(s); and/or other deposition-facilitating or composition-stabilizing component(s), as necessary or desired for such applications. Importantly, the precursor component containers 330 include the precursor components either in neat liquid form or in solution form, e.g., a liquid or solid precursor dissolved in an appropriate amount of solvent.

The precursor solution may be pumped to the mixing chamber 322 via chemical mixing chamber line 334 or pumped directly to the process chamber 324 via chemical process chamber line 336. The latter option may be used during the pulsed deposition process described hereinabove.

In the mixing chamber 322, an amount of pre-mixed precursor components are mixed with an amount of SCCO₂ to form the precursor-containing SCF solution. The amount of the individual components is readily determinable by one skilled in the art based on the thin films to be deposited and the processing conditions. The resulting precursor-containing SCF solution may include all components in the supercritical state or alternatively, at least one of the components is not in the supercritical state but instead is solvated in the supercritical fluid.

The precursor-containing SCF solution may be introduced into the process chamber 324 via precursor-containing SCF process chamber line 338 having a check valve 340 disposed therein. For example, the precursor-containing SCF may be continuously introduced into the process chamber 324 or alternatively, the precursor-containing SCF may be delivered in pulses as described hereinabove. Alternatively, the precursor-containing SCF may be exhausted from the mixing chamber 322 via mixing chamber exhaust line 350. A back pressure regulator (BPR) 372 may be provided in the mixing chamber exhaust line, to depressurize the remaining fluid. Egress of the precursor-containing SCF may be effectuated when the process chamber is offline or during standard maintenance of the deposition apparatus.

Following deposition of the thin film in the process chamber 324, the remaining fluid comprising unreacted precursor-containing SCF and products of the decomposition reaction at the microelectronic device are exhausted from the process chamber 324 via process chamber exhaust line 360. The remaining fluid may pass through an imine filter 362, a back pressure regulator 364 and a check valve 366 prior to entering a separator 370. The separator separates the phases and constituents of the cleaning discharge, and may provide for reclamation for other uses or return lines for reclaimed cleaning fluid or additives that can be reused at the supply side of the system. Such a separation may be made through the manipulation of phase changes or other chemical or physical processes.

The invention includes various pressure, temperature, and level transmitters, manual and automatic control valves, check valves, relief valves, rupture disks, shut-off valves, isolation valves, over-pressure relief valves, mass-flow control valves and interconnecting piping and other hardware necessary to operate the process safely and effectively. The invention may be controlled by a digital controller in a control panel with appropriate user interface and display of information necessary for an operator to control and monitor the system.

Importantly, the mixing chamber and the process chamber are high pressure vessels of comparable volume to reduce pressure swings and non-optimized performance. Furthermore, the process chamber may include mixing capabilities so that the process chamber is also the mixing chamber, and vice versa. The continuous-flow dynamic apparatus described herein may be readily altered by one skilled in the art to include only one high pressure vessel for mixing and processing therein.

Liquid chemical and SCCO₂ process equipment should be made entirely of chemical resistant metals. Materials used in the process chambers should not flake, corrode, etch or outgas during processing, and compatible with process chemicals, operating pressures and temperatures, and should be able to withstand the necessary cleaning processes. Although all corrosion-resistant materials protect themselves by forming a protective oxide layer on the surface of the metal, e.g., aluminum forms aluminum oxide (Al₂O₃) and stainless steel forms chrome oxide (Cr₂O₃), these oxides will pit if exposed to halogen salts. In addition, all concentrations of hydrochloric acid will corrode the 300 series of stainless steel, even at low temperatures, and in dilute solutions, sulfuric, phosphoric and nitric acid readily attack T316SS (including 65 wt. % iron, 12 wt. % nickel, 17 wt. % chromium, 2.5 wt. % molybdenum, 2 wt. % manganese and 1 wt. % silicon) at elevated temperatures and pressures.

To avoid corrosion and/or pitting of the materials of construction of the apparatus, preferably nickel-based alloys are used, particularly in the mixing and/or process chambers. For example, super nickel alloys are known for their excellent resistance to severe corrosive conditions. A list of common, commercially available alloys that are resistant to chloride pitting and thus may be used as the material of construction for the SCCO₂ apparatus described herein is provided hereinbelow:

### Alloy 400

Alloy 400 is an alloy including 66 wt. % nickel, 31.5 wt. % copper, and 1.2 wt. % iron. For many applications it offers about the same corrosion resistance as nickel, but with higher maximum working pressures and temperatures and at a lower cost because of its greatly improved machinability. Alloy 400 is widely used in the presence of caustic solutions and/or chloride salts because it is not subject to stress corrosion cracking in most applications. It is also an excellent material for fluorine, hydrogen fluoride and hydrofluoric acid systems. Alloy 400 offers some resistance to hydrochloric and sulfuric acids at modest temperatures and concentrations, but it is seldom the material of choice for these acids. As would be expected from its high copper content, Alloy 400 is rapidly attacked by nitric acid and ammonia systems.

### Alloy 600

Alloy 600 is a high nickel alloy including 76 wt. % nickel, 15.5 wt. % chromium, and 8 wt. % iron and offers excellent resistance to caustics and chlorides at high temperatures and high pressures when sulfur compounds are present. It also is often chosen for its high strength at elevated temperatures. Although it can be recommended for a broad range of corrosive conditions, its cost often limits its use to only those applications where its exceptional characteristics are required.

### Alloy B-2/B-3

Alloy B-2 includes 66 wt. % nickel, 28 wt. % molybdenum, 2 wt. % iron, 1 wt. % chromium, 1 wt. % manganese and 1 wt. % cobalt, and alloy B-3 includes 65 wt. % nickel, 28.5 wt. % molybdenum, 1.5 wt. % iron, 1.5 wt. % chromium, 3 wt. % manganese, 1 wt. % cobalt and 3 wt. % tungsten. Both have been developed primarily for resistance to reducing acid environments, particularly hydrochloric, sulfuric and phosphoric acids. Their resistance to these acids in pure forms is unsurpassed, but the presence of ferric and other oxidizing ions in quantities as low as 50 ppm can dramatically degrade the resistance of these alloys.

### Alloy C-276

Alloy C-276 is a nickel-chromium-molybdenum alloy including 53 wt. % nickel, 15.5 wt. % chromium, 16 wt. % molybdenum, 6.5 wt. % iron, 4 wt. % tungsten, 2.5 wt. % cobalt and 1 wt. % manganese, and has perhaps the broadest general corrosion resistance of all commonly used alloys. It was developed initially for use with wet chlorine, but it also offers excellent resistance to strong oxidizers such as cupric and ferric chlorides, and to a variety of chlorine compounds and chlorine contaminated materials. Because of its broad chemical resistance, Alloy C-276 is the second most popular alloy, following T316SS, for vessels used in research and development work.

### Nickel 200

Nickel 200 is one of the designations of commercially pure nickel. It offers the ultimate in corrosion resistance to hot caustic environments, but its applications are severely restricted because of its poor machinability and resultant high fabrication costs.

The apparatus of FIG. 6 is a continuous-flow SCFD apparatus as opposed to most SCF systems, which are static, or recirculatory. The present invention allows for the removal of undesirable products of the decomposition reaction from the process chamber at the same time that fresh precursor-containing SCF solution enters the process chamber. This allows for more efficient deposition and minimized contaminant re-deposition at the wafer surface.

Removal of Materials and Residues from a Microelectronic Device

A schematic of a continuous-flow dynamic removal apparatus 300 of the present invention is also illustrated in FIG. 6 as described hereinabove. The removal apparatus in constructed analogously to the aforementioned deposition apparatus, with the exception that the apparatus of FIG. 6 must be adapted for removal processes, e.g., different process chambers, chemical components, etc.

The continuous-flow apparatus and process described herein may be employed for etching, cleaning, residue removal, thin-film deposition and the removal of layers and/or residue from a microelectronic device using supercritical or subcritical fluid mediums. Preferably, the layers removed using the continuous-flow apparatus described herein include hardened photoresist on a patterned microelectronic device surface. Specific reference to supercritical carbon dioxide hereinafter in the broad description of the invention is meant to provide an illustrative example of the present invention and is not meant to limit same in any way.

In a continuous-flow process, prior to introducing the chemical formulation components, e.g., co-solvent and chemical additives, into the process chamber, the process chamber is filled with neat solvent (which is the same as the solvent in the SCF-formulation) at supercritical pressure and supercritical temperature. Thereafter, an essentially homogeneous SCF-formulation is continuously added to the process chamber containing at least one microelectronic device, as removed products and/or unused SCF-formulation are continuously removed from the process chamber. The flow rates into and out of the process chamber are made approximately equal so that the pressure within the process chamber remains substantially constant, ensuring the maintenance of a supercritical state.

The temperature and pressure of the continuous-flow process depends on the chemical component(s) and choice of solvent. Generally, temperature is less than 250° C. and often less than 100° C., while the pressure is typically between 50 and 500 bar.

Solubility of the chemical component(s) in the supercritical solvent at the process conditions can be verified in a variable volume view cell, which is well known in the art (e.g., McHugh et al, Supercritical Fluid Extraction: Principles and Practice; Butterworths: Boston, 1986). Known quantities of chemical component(s) and supercritical solvent are loaded into the view cell, where they are heated and compressed to conditions at which a single phase is optically observed.

The process chamber 324 may be any chamber necessary for SCF removal processes including, but not limited to, etching, cleaning, particle removal, post-etch residue removal and hardened photoresist removal, as readily determinable by one skilled in the art. The chamber may be a batch or single wafer chamber, for continuous, pulsed or static processing.

Similar to the SCFD apparatus, chemical components from chemical component containers 330 are introduced into the chemical component pump 332 for pre-mixing therein. Chemical formulation pump 332 is a high pressure liquid pump. Although, four (4) chemical component containers 330 are illustrated in FIG. 6, more or less containers are contemplated herein, as required for the particular material to be processed. Chemical components include, but are not limited to: co-solvent(s); oxidizing agent(s); reducing agent(s); surfactant(s); passivator(s); chelating agent(s); etchant(s); and/or other process component(s), as necessary or desired for such applications. Importantly, the chemical component containers 330 include the chemical components either in neat liquid form or in solution form, e.g., a liquid or solid chemical dissolved in an appropriate amount of solvent.

In the mixing chamber 322, an amount of pre-mixed chemical components are mixed with an amount of SCCO₂ to form the SCCO₂ formulation. The amount of the individual components is readily determinable by one skilled in the art based on the layers to the cleaned/removed and the processing conditions. The resulting SCCO₂ formulation may include all components in the supercritical state or alternatively, at least one of the components is not in the supercritical state but instead is solvated in the supercritical fluid.

Following cleaning/removal of the unwanted layers in the process chamber 324, the remaining fluid comprising unreacted SCCO₂ formulation and removed products, is exhausted from the process chamber 324 via process chamber exhaust line 360. The remaining fluid may pass through an in-line filter 362, a back pressure regulator 364 and a check valve 366 prior to entering a separator 370. The separator separates the phases and constituents of the process discharge, and may provide for reclamation for other uses or return lines for reclaimed processing fluid or additives that can be reused at the supply side of the system. The separation may be made through the manipulation of phase changes or other chemical or physical processes.

Similar to the SCFD apparatus, the mixing chamber and the process chamber are preferably nickel-based alloy high pressure vessels of preferably comparable volume to reduce pressure swings and non-optimized performance. Furthermore, the process chamber may include mixing capabilities so that the process chamber is also the mixing chamber, and vice versa. The continuous-flow dynamic apparatus described herein may be readily altered by one skilled in the art to include only one high pressure vessel for mixing and processing therein.

The invention may include various pressure, temperature, and level transmitters, manual and automatic control valves, check valves, relief valves, rupture disks, shut-off valves, isolation valves, over-pressure relief valves, mass-flow control valves and interconnecting piping and other hardware necessary to operate the process safely and effectively. The invention may be controlled by a digital controller in a control panel with appropriate user interface and display of information necessary for an operator to control and monitor the system.

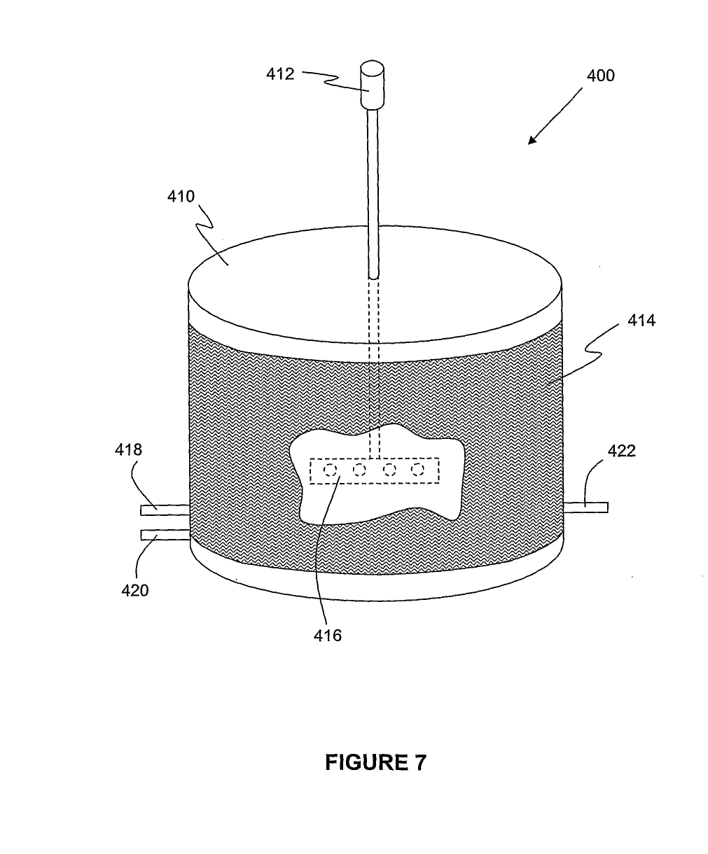

An embodiment of the mixing chamber is illustrated in FIG. 7. Preferably, the mixing chamber is a dynamic mixing chamber whereby the bulk solvent, co-solvent and chemical additives are thoroughly mixed. The dynamic mixing chamber of the present invention may be used to mix a wide variety of solid/liquid suspension systems, including simple, dilute fluid suspensions as well as complex, concentrated slurries which may exhibit anomalous viscosity characteristics.

The dynamic mixing chamber 400 is a high pressure vessel 410, preferably having the same volume as the process chamber. It is to be appreciated by one skilled in the art that the walls of the high pressure vessel 410 define a circular, elliptical or polygonal shaped mixing chamber. The dynamic mixing chamber is preferably equipped with a heater 414, such as a jacket (as shown in FIG. 7), heating rods or cartridges, said heater circumscribing the exterior walls of the dynamic mixing chamber. SCF inlet port 418, co-solvent/chemical additive inlet port 420 and SCCO₂ formulation outlet port 422 are illustratively shown to be positioned at the gravitational bottom of the dynamic mixing chamber, however, it is to be appreciated that their positioning is not limited to the locations illustrated in FIG. 7.

The dynamic mixing chamber 400 includes a motorized agitator, for example a magnetic stir-bar that rests on the gravitational bottom of the high pressure vessel 410 (not shown) or alternatively, a multi-bladed impeller 416 that is suspended within the high pressure vessel at the end of a motorized column 412. The agitator may be any size or shape, as readily determined by one skilled in the art.

Optionally, the multi-bladed impeller 416 includes openings communicatively connected to a hollow motorized column 412. In practice, gases may be introduced into the mixing chamber by passing the gas down the hollow motorized column for egress out the impeller openings.

The dynamic mixing chamber described herein ensures a homogeneous SCCO₂ formulation for delivery to the process chamber, thereby improving the cleaning/removal ability of the formulation relative to an apparatus having a static mixing system. As defined herein, a “homogeneous” SCCO₂ formulation corresponds to a solution wherein at least 95% of the total volume of components, e.g., SCCO₂, co-solvent, etc., are miscible, preferably at least 98%, most preferably at least 99%.

The features and advantages of the invention are more fully shown by the illustrative examples discussed below.

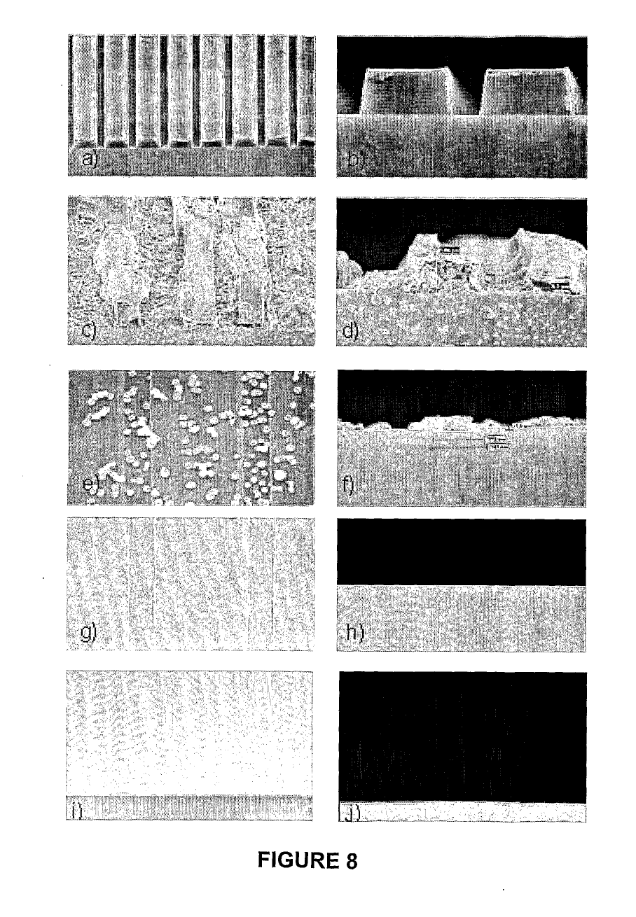

A series of experiments were performed to determine the effects of mixing, i.e., dynamic versus static, on the removal efficiency of hardened photoresist from a microelectronic device. The sample device was a patterned silicon wafer having a thin chemical oxide layer and a high-dose ion-implanted organic photoresist layer thereon. Micrographs of the sample wafer before processing are shown in FIGS. 8a (top left 60° angle view) and 8b (right 90° cross section view).

The sample wafer was processed with a SCCO₂ formulation including 12 wt. % co-solvent component(s). The SCCO₂ was mixed with the 12 wt. % co-solvent component(s) using a static mixing chamber. The processing apparatus (not shown) further included a re-circulator whereby the solution egressing from the process chamber was subsequently reintroduced to the process chamber for reuse therein. The processing parameters included static mixing/recirculation for 10 minutes followed by a 4 min methanol/SCCO₂ rinse. The 10 min cleaning, 4 min rinse cycle was repeated a total of three times. Referring to FIGS. 8c and 8d, which correspond to micrographs 8a and 8b, respectively, after processing, it can be seen that not all of the photoresist material was removed using the static mixing/recirculation system. Specifically, the photoresist lying below the hardened ion-implanted crust was removed but the hardened crust was not (the crust collapsed in the absence of the supporting non-hardened photoresist). This is believed to be the result of inadequate mixing of the SCCO₂, co-solvent and chemical additives in the static mixer prior to introduction to the process chamber. In addition, the recirculation of the spent fluid over the sample surface did not allow for fresh incoming chemistry, which is necessary for proper cleaning/removal. Importantly, during the recirculation cycle, any small changes in process conditions, i.e., pressure or temperature, may induce phase separation, resulting in the precipitation of the co-solvent(s), chemical additive(s) and/or residues.

The importance of introducing clean chemistries to the process chamber was supported by the following experiment. The SCCO₂ was mixed with the 12 wt. % co-solvent component(s) using the static mixing chamber of the present invention. The processing apparatus was similar to the apparatus shown in FIG. 6, whereby the solution egressing from the process chamber was directed to a separator and as such, fresh formulation must be introduced to the process chamber during each subsequent cleaning cycle. The processing parameters included static mixing/simulated continuous flow for 2 minutes followed by a methanol/SCCO₂ rinse. The 2 min cleaning, rinse cycle was repeated a total of three times with fresh chemistries. “Simulated” continuous-flow was achieved by introducing fresh aliquots of the SCCO₂ formulation during each cleaning cycle. The hardened photoresist was completely removed, however, some precipitation at the patterned surface was observed (see FIGS. 8e and 8f). Although not wishing to be bound by theory, it is assumed that the precipitation was the result of inadequate mixing in the static mixer as well as a substantially saturated SCCO₂ solvent.

The exact same process was repeated using a 6 wt. % formulation to determine if increasing the capacity of the SCCO₂ for solutes, i.e., using a more undersaturated solution, would eliminate the spherical-shaped precipitation seen in FIGS. 8e and 8f Referring to FIGS. 8g and 8h, it can be seen that short cleaning cycles in conjunction with smaller concentrations of co-solvents, thereby simulating dynamic mixing and a continuous flow process, efficiently removes photoresist and all spherical-shaped particles. That said, this multiple-step process increases process time and as such, is undesirable.

The incorporation of dynamic mixing can simplify the process and reduce cleaning times. When the continuous-flow apparatus of FIG. 6 is used with the dynamic mixer, the photoresist is completely removed (see FIGS. 8i and 8j).

Accordingly, while the invention has been described herein in reference to specific aspects, features and illustrative embodiments of the invention, it will be appreciated that the utility of the invention is not thus limited, but rather extends to and encompasses numerous other aspects, features and embodiments. Accordingly, the claims hereafter set forth are intended to be correspondingly broadly construed, as including all such aspects, features and embodiments, within their spirit and scope.

1. A continuous-flow supercritical fluid (SCF) apparatus, said SCF apparatus comprising:
(a) a solvent container holding a solvent;
(b) a high pressure solvent pump communicatively connected to the solvent container for flowing the solvent downstream of the high pressure solvent pump;
(c) a solvent heater communicatively connected to and positioned downstream of the high pressure solvent pump, wherein the solvent heater is arranged to convert the solvent into a supercritical state;
(d) a high pressure chemical component pump for flowing at least one chemical component downstream of the chemical component pump;
(e) a mixing chamber communicatively connected to and positioned downstream of both the solvent heater and the chemical component pump; and
(f) a process chamber communicatively connected to and positioned downstream of the solvent heater and the mixing chamber,
wherein the process chamber is pressure rated to withstand pressure in a range from 50 bar to 500 bar.

2. (canceled)

3. A supercritical fluid (SCF) process chamber comprising:
(a) an interior chamber;
(b) a fluid disperser positioned within the interior chamber;
(c) a microelectronic device support positioned within the interior chamber, arranged to support one or more microelectronic devices; and
(d) at least two exhaust ports distally positioned relative to the fluid disperser,
wherein said SCF process chamber is useful for the deposition of thin films on microelectronic devices.

4. The SCF process chamber of claim 3, wherein the fluid disperser comprises a showerhead.

5. The SCF process chamber of claim, wherein the fluid disperser is axially adjustable along the length of the SCF process chamber to vary the distance between the fluid disperser and the microelectronic device.

6. The SCF process chamber of claim 3, wherein the at least two exhaust ports are positioned in proximity to the microelectronic device.

7. The SCF process chamber of claim 3, wherein the at least two exhaust ports are symmetrically positioned about the circumference of the SCF process chamber.

8. The SCF process chamber of claim 3, further comprising a heating element located at or within the microelectronic device support.

9. The SCF process chamber of claim 8, wherein the heating element comprises at least one resistive cartridge heater located within the microelectronic device support.

10. (canceled)

11. The SCF process chamber of claim 8, wherein the heating element comprises a conductive thin film.

12. The SCF process chamber of claim 3, wherein the process chamber comprises a high pressure container and a high pressure top, wherein the high pressure container and high pressure top are matebly engageable and define the interior chamber.

13. The SCF process chamber of claim 3, arranged to maintain the solvent in the supercritical state upstream and downstream of the fluid disperser.

14.-22. (canceled)

23. The SCF apparatus of claim 1, wherein the mixing chamber is selected from the group consisting of a static mixing chamber and a dynamic mixing chamber.

24. (canceled)

25. (canceled)

26. The SCF apparatus of claim 23, wherein the dynamic mixing chamber comprises:
(a) a high pressure vessel defining an interior chamber; and
(b) an agitator positioned within the interior chamber to provide dynamic mixing, whereby the SCF and at least one chemical component are homogenized.

27.-31. (canceled)

32. A method of removing ion-implanted photoresist from a microelectronic device having photoresist material thereon using the SCF apparatus of claim 1.

33. (canceled)

34. A method of depositing thin films onto a microelectronic device using the SCF process chamber of claim 3.

35.-41. (canceled)

42. The SCF process chamber of claim 3, wherein the process chamber is pressure rated to withstand pressure in a range from 50 bar to 500 bar.

43. The SCF process chamber of claim 3, wherein the fluid disperser comprises a housing enclosing an interior volume therewithin, wherein the housing is joined in flow communication with a precursor-containing SCF.

44. The SCF process chamber of claim 3, wherein the fluid disperser comprises a plurality of openings to uniformly distribute a precursor-containing SCF.

45. The method of depositing thin films according to claim 34, wherein the fluid disperser is axially adjusted along the length of the SCF process chamber to control the residence time of a precursor-containing SCF at the microelectronic device.

46. A method of cleaning a microelectronic device using the SCF process chamber of claim 3, comprising providing a cleaning formulation and a SCF, premixing the cleaning formulation and the SCF to form a SCF-cleaning solution, and contacting the cleaning solution and the microelectronic device in the SCF process chamber to effect cleaning or removal of a selected material from a surface of the microelectronic device.

47. A method of cleaning a microelectronic device using the SCF apparatus of claim 1.
